(19) United States
(12) Patent Application Publication
(10) Pub. No.: US 2018/0211961 A1
(43) Pub. Date: Jul. 26, 2018

(54) SEMICONDUCTOR MEMORY DEVICE AND MANUFACTURING METHOD THEREOF

(71) Applicants: UNITED MICROELECTRONICS CORP., Hsin-Chu City (TW); Fujian Jinhua Integrated Circuit Co., Ltd., Quanzhou City (CN)

(72) Inventors: Ger-Pin Lin, Tainan City (TW); Yung-Ming Wang, Taichung City (TW); Ting-Pang Chung, Taichung City (TW); Tien-Chen Chan, Tainan City (TW); Shu-Yen Chan, Changhua County (TW)

(21) Appl. No.: 15/877,356

(22) Filed: Jan. 22, 2018

(30) Foreign Application Priority Data
Jan. 26, 2017 (CN) 201710061438.4

(51) Int. Cl. H01L 27/108; H01L 49/02

(52) U.S. Cl. CPC H01L 27/1087; H01L 27/10888; H01L 27/10829; H01L 28/60

(57) ABSTRACT

A semiconductor memory device and a manufacturing method thereof are provided in the present invention. Storage node contacts are formed on a semiconductor substrate including active regions. Each storage node contact contacts at least one of the active regions. Each storage node contact has a recessed top surface. A first distance exists between a topmost point and a lowest point of the recessed top surface in a vertical direction. A second distance exists between the topmost point and a bottom surface of the storage node contact in the vertical direction. A ratio of the first distance to the second distance ranges from 30% to 70%. The contact resistance between the storage node contact and other conductive structures formed on the storage node contact may be reduced by the storage node contact having the recessed top surface, and the electrical operation condition of the semiconductor memory device may be improved accordingly.

### BACKGROUND OF THE INVENTION

### 1. Field of the Invention

The present invention relates to a semiconductor memory device and a manufacturing method thereof, and more particularly, to a semiconductor memory device including storage node contacts and a manufacturing method thereof.

### 2. Description of the Prior Art

Dynamic random access memory (hereinafter referred to as DRAM) is a type of volatile memory, which is indispensable in many electronic devices. DRAM is formed by a large amount of memory cells that form an array region, so as to store data, while each memory cell is formed by connecting a metal oxide semiconductor (MOS) and a capacitor in series.

According to the need of the products, the density of the memory cells in the array region has to be continuously increased, which leads to higher difficulty and complexity of the related process and design. For example, when the size of the contact structure electrically connected to the elements in the memory cell needs to be relative small because of the increased density of the memory cell, the contact area between the contact structure and the other structures that need to be in contact with the contact structure so as to being electrically connected to the contact structure would be relatively small, and the contact resistance between the two elements would be increased and has a negative effect on the operation and performance of the memory cell accordingly.

### SUMMARY OF THE INVENTION

The present invention provides a semiconductor memory device and a manufacturing method thereof. A storage node contact having a recessed top surface is formed to increase a contact area between the storage node contact and other conductive structure on the storage node contact, the contact resistance between the conductive structure and the storage node contact is reduced, and the electrical operation condition of the semiconductor memory device may be improved accordingly.

According to an embodiment of the present invention, a manufacturing method of a semiconductor memory device that includes the following steps is provided. First, a semiconductor substrate that includes active regions is provided. Storage node contacts are formed on the semiconductor substrate. Each of the storage node contacts is in contact with at least one of the active regions and each of the storage node contacts has a recessed top surface. A first distance exists between a topmost point and a lowest point of the recessed top surface in a vertical direction perpendicular to the semiconductor substrate, a second distance exists between the topmost point of the recessed top surface and a bottom surface of the storage node contact in the vertical direction, and a ratio of the first distance to the second distance ranges from 30% to 70%.

According to an embodiment of the present invention, a semiconductor memory device is provided. The semiconductor memory device includes a semiconductor substrate and storage node contacts. The semiconductor substrate includes active regions. The storage node contacts are disposed on the semiconductor substrate, each of the storage node contacts is in contact with at least one of the active regions, and each of the storage node contacts has a recessed top surface. A first distance exists between a topmost point and a lowest point of the recessed top surface in a vertical direction perpendicular to the semiconductor substrate, a second distance exists between the topmost point of the recessed top surface and a bottom surface of the storage node contact in the vertical direction, and a ratio of the first distance to the second distance ranges from 30% to 70%.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams illustrating a manufacturing method of a semiconductor memory device according to an embodiment of the present invention, wherein

FIG. 2 is a schematic diagram illustrating the condition after FIG. 1;

FIG. 3 is a schematic diagram illustrating the condition after FIG. 2;

FIG. 4 is a schematic diagram illustrating the condition after FIG. 3;

FIG. 5 is a schematic diagram illustrating the condition after FIG. 4;

FIG. 6 is a schematic diagram illustrating the condition after FIG. 5; and

FIG. 7 is a schematic diagram illustrating the condition after FIG. 6.

### DETAILED DESCRIPTION

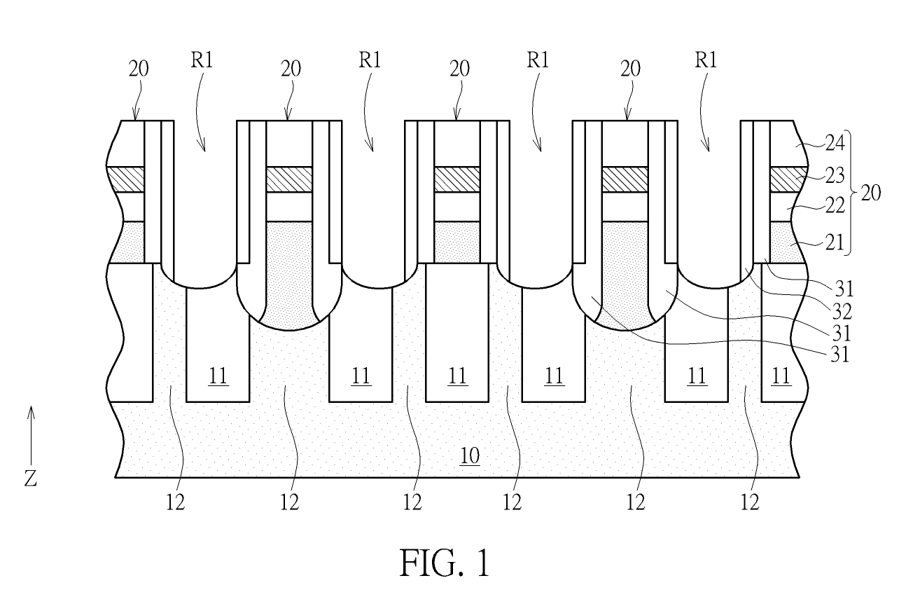

Referring to FIG. 1 to FIG. 7, FIG. 1 to FIG. 7 are schematic diagrams illustrating a manufacturing method of a semiconductor memory device according to an embodiment of the present invention. In this embodiment, a manufacturing method of a semiconductor memory device is provided, and the manufacturing method includes the following steps. First, as shown in FIG. 1, a semiconductor substrate 10 that includes active regions 12 is provided. The semiconductor substrate 10 may include a silicon substrate, an epitaxial silicon substrate, a silicon-germanium substrate, a silicon carbide substrate or a silicon-on-insulator (SOI) substrate, but not limited thereto. Shallow trench isolations 11 are formed in the semiconductor substrate 10 for defining the active regions 12. The shallow trench isolations 11 may be formed by forming trenches in the semiconductor substrate 10 by etching and then filling the trenches with insulation materials such as silicon oxide or silicon oxynitride, but not limited thereto. In some embodiments, depending on the condition, other appropriate methods may also be used to form the shallow trench isolations 11. Besides, word lines (not shown), such as buried word lines, may be formed in the semiconductor substrate 10, but not limited thereto.

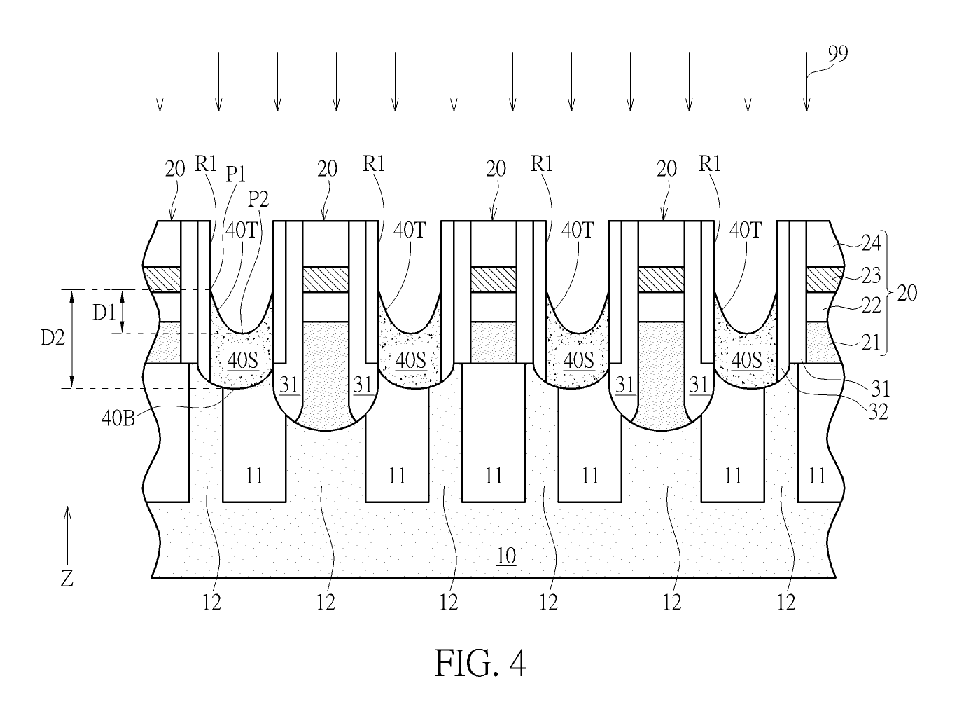

Next, as shown in FIG. 4, storage node contacts 40S are formed on the semiconductor substrate 10. Each of the storage node contacts 40S is in contact with at least one of the active regions 12, and each of the storage node contacts 40S has a recessed top surface 40T. A first distance D1 exists between a topmost point P1 of the recessed top surface 40T and a lowest point P2 of the recessed top surface 40T in a vertical direction Z perpendicular to the semiconductor substrate 10, a second distance D2 exists between the topmost point P1 of the recessed top surface 40T and a bottom surface 40B of the storage node contact 40S in the vertical direction Z, and a ratio of the first distance D1 to the second distance D2 (D1/D2) ranges from 30% to 70%, so as to increase the surface area of the top surface of each storage node contact 40S and reduce the contact resistance between the storage node contact 40S and other conductive structure subsequently formed on the storage node contact 40S. The electrical operation condition of the semiconductor memory device may be improved accordingly.

The method of forming the storage node contacts 40C may include but is not limited to the following steps. First, as shown in FIG. 1, grooves R1 are formed on the semiconductor substrate 10, wherein each of the grooves R1 is formed corresponding to one of the active regions 12 and each of the grooves R1 exposes the corresponding active region 12. To be more specific, the manufacturing method in this embodiment may further include forming bit line structures 20 on the semiconductor substrate 10, each of the bit line structures 20 is formed corresponding to at least one of the active regions 12, and at least some of the grooves R1 are formed between the bit line structures 20. Each bit line structure 20 may be in contact with the corresponding active region 12, and each bit line structure 20 may include a contact plug 21, a barrier layer 22, a low resistivity layer 23 and a capping layer 24 stacked sequentially in the vertical direction Z. The contact plug 21 may include silicon-containing conductive materials such as poly-silicon or amorphous silicon, the barrier layer 22 may include titanium, tungsten silicide (WSi), tungsten nitride (WN) or other appropriate barrier materials, the low resistivity layer 23 may include materials with relatively lower resistivity, such as aluminum, tungsten, copper, titanium aluminide (TiAl) or other appropriate conductive materials with low resistivity, and the capping layer 24 may include insulation materials such as silicon nitride, but not limited thereto. Besides, a spacer 31 may be formed on sidewalls of the contact plug 21, the barrier layer 22, the low resistivity layer 23 and the capping layer 24, and a dielectric layer 32 may be formed between the bit line structures 20. The dielectric layer 32 covers the active region 12, and the grooves R1 penetrate the dielectric layer 32 and expose the corresponding active regions 12. The dielectric layer 32 may include silicon nitride, silicon oxynitride, silicon carbon nitride or other appropriate dielectric materials, but not limited thereto.

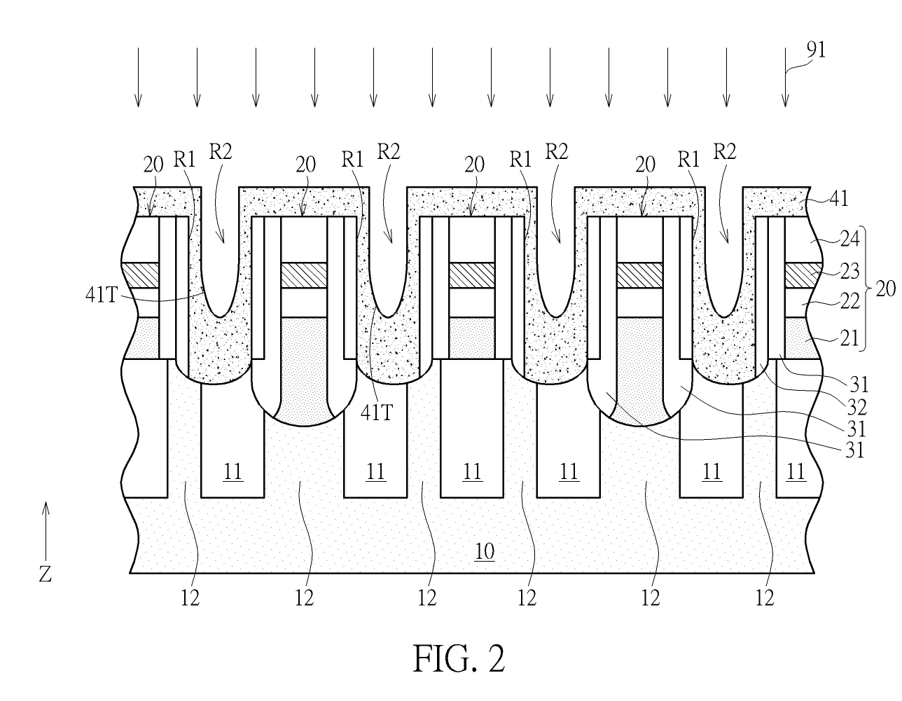

Next, as shown in FIG. 1 and FIG. 2, a first conductive layer 41 is formed on the semiconductor substrate 10, at least a portion of the first conductive layer 41 is filled into each of the grooves R1, and each of the grooves R1 is not fully filled with the first conductive layer 41. In some embodiments, the first conductive layer 41 may be formed by a first deposition process 91, and the first deposition process 91 may include a chemical vapor deposition (CVD) process, a physical vapor deposition (PVD) process or other appropriate deposition processes. By controlling the process parameters of the firs deposition process 91, each of the grooves R1 may not be fully filled with the first conductive layer 41, and the surface 41T of the first conductive layer 41 in each of the grooves R1 has a recess R2 pointing downward at a center part of the recess R2. Besides, the first conductive layer 41 may include a silicon-containing conductive layer, such as an amorphous silicon layer and a polysilicon layer, or other appropriate non-silicon conductive layer.

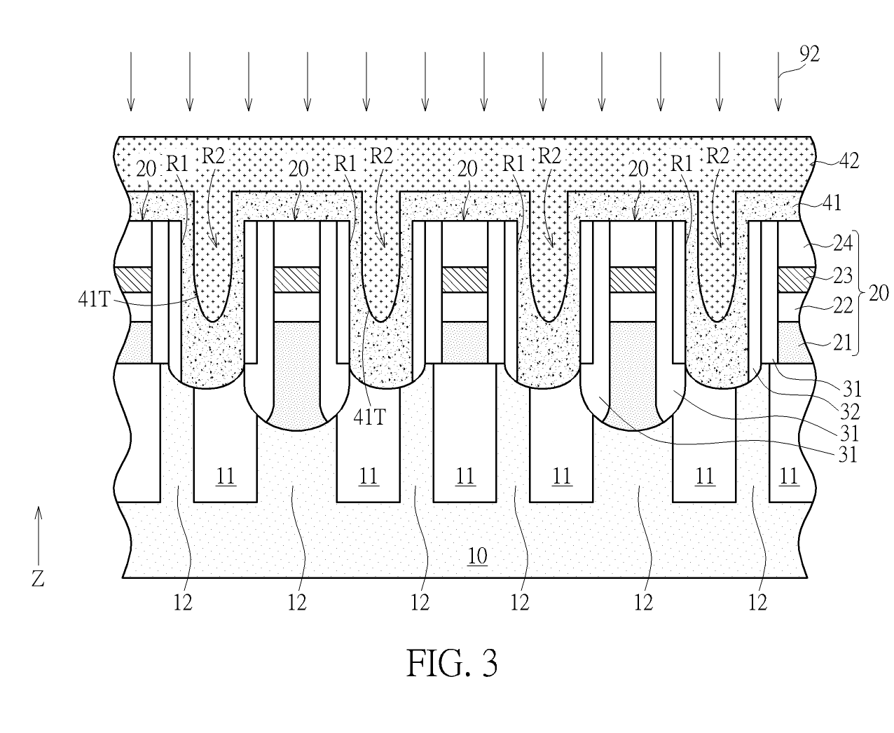

And then, as shown in FIG. 2 and FIG. 3, a second conductive layer 42 is formed on the first conductive layer 41. At least a portion of the second conductive layer 42 is filled into each of the grooves R1, and at least a portion of the second conductive layer 42 is formed in the recess R2. In other words, the second conductive layer 42 formed in each of the grooves R1 is surrounded by the first conductive layer 41 in a horizontal direction, and in the present embodiment, each groove R1 may be fully filled with the first conductive layer 41 and the second conductive layer 42, but not limited thereto. In some embodiments of the present invention, each of the grooves R1 may not be fully filled with the first conductive layer 41 and the second conductive layer 42. In some embodiments, the second conductive layer 42 may be formed by a second deposition process 92, and the second deposition process 92 may include a chemical vapor deposition process, a physical vapor deposition process or other appropriate deposition processes. In some embodiments, the first conductive process 91 used to form the first conductive layer 41 and the second conductive process 92 used to form the second conductive process 42 maybe the same process and may be performed continuously in the same equipment and/or in the same process chamber, but not limited thereto. In some embodiments of the present invention, depending on the condition, the first deposition process 91 and second deposition process 92 may be different from each other for forming the first conductive layer 41 and the second conductive layer 42 respectively. Besides, the second conductive layer 42 may include a silicon-containing conductive layer such as an amorphous silicon layer and a polysilicon layer, or other appropriate non-silicon conductive layer. In other words, the material of the first conductive layer 41 may be identical to or different from the materials of the second conductive layer 42.

Next, as shown in FIG. 3 and FIG. 4, an etching back process 99 is performed to the first conductive layer 41 and the second conductive layer 42 to form the storage node contacts 40S in the grooves R1. It is worth to know that the etching rate of the second conductive layer 42 is higher than the etching rate of the first conductive layer 41 in the etching back process, so as to form the storage node contacts 40S having the recessed top surface 40T and increase the first distance D1 between the topmost point P1 of the recessed top surface 40T and the lowest point P2 of the recessed top surface 40T, and the area of the recessed top surface 40T is increased accordingly. To increase the area of the top surface of each storage node contact 40S, the above mentioned first distance D1 has to be increased relatively. However, on the other hands, it is necessary to consider the etching uniformity of the etching back process 99 and a certain thickness has to be kept at the center part of the storage node contact 40S. Accordingly, the ratio of the first distance D1 to the second distance D2 (D1/D2) may range from 30% to 70%, and the ratio may be further controlled to range from 50% to 70% or from 60% to 70%, for example, but not limited thereto.

Besides, to realize the above mentioned etching effect, the density of the first conductive layer 41 is higher than the density of the second conductive layer 42. For example, when the material of the first conductive layer 41 is the same as the material of the second conductive layer 42 (such as both are amorphous silicon conductive material), the density of the first conductive layer 41 may be different from the density of the second conductive layer 42 by adjusting the process parameters of the first deposition process configured to form the first conductive layer 41 and the process parameters of the second deposition process configured to form the second conductive layer 42. For example, the deposition rate of the first deposition process may be lower than the deposition rate of the second deposition process, so as to make the density of the first conductive layer 41 higher than the density of the second conductive layer 42. Besides, a process temperature of the first deposition process may be lower than a process temperature of the second deposition process. For example, the process temperature of the first deposition process may be about 380° C., and the process temperature of the second deposition process may ranges from 500° C. to 600° C., so as to make the deposition rate of the first deposition process lower than the deposition rate of the second deposition process, but not limited thereto. In some other embodiments of the present invention, depending on the condition, other process parameters in the first deposition process and the second deposition process maybe adjusted to realize the above mentioned effect of the etching rate difference in the etching back process 99. Besides, when the material of the first conductive layer 41 is the same as the material of the second conductive layer 42 (such as both are amorphous silicon conductive material) and the deposition rate of the first deposition process is lower than the deposition rate of the second deposition process, the resistivity of the first conductive layer 41 is lower than the resistivity of the second conductive layer 42. The conductive property of the storage node contact 40S formed under this condition would not be negatively affected.

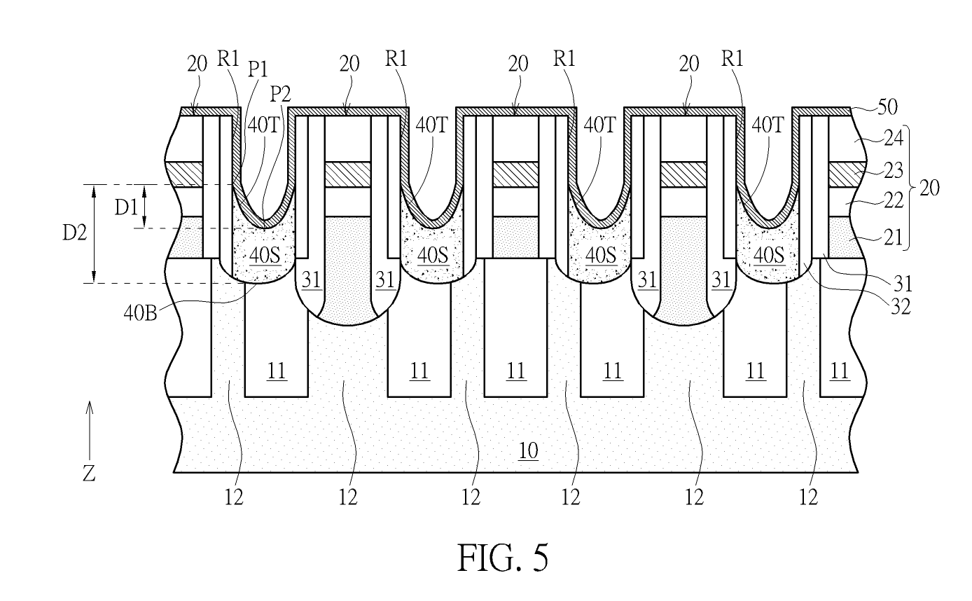

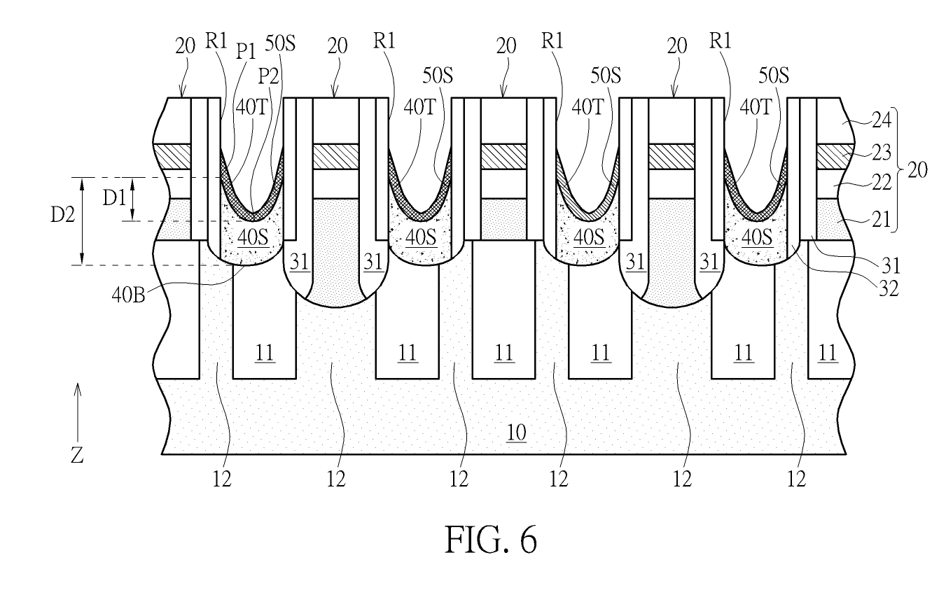

Next, as shown in FIG. 5 and FIG. 6, the manufacturing method of the present invention may further include forming a metal silicide layer 50S on each of the storage node contacts 40S. Each of the metal silicide layer 50S is formed conformally on the recessed top surface 40T of the corresponding storage node contact 40S. The forming method of the metal silicide layer 50S may include but is not limited to the following steps. First, a metal layer 50 is formed covering the recessed top surface 40T of the storage node contact 40S, and then a thermal treatment is performed to form the metal silicide layer 50S on the storage node contact 40S. After the metal silicide layer 50S is formed, the metal layer 50 is removed. In some embodiments, the metal layer 50 may include cobalt, nickel or other appropriate metal material, and the metal silicide 50S may include cobalt-silicide, nickel-silicide or other appropriate metal silicide. Besides, the metal layer 50 may be formed by a deposition apparatus such as a physical vapor deposition apparatus, but not limited thereto.

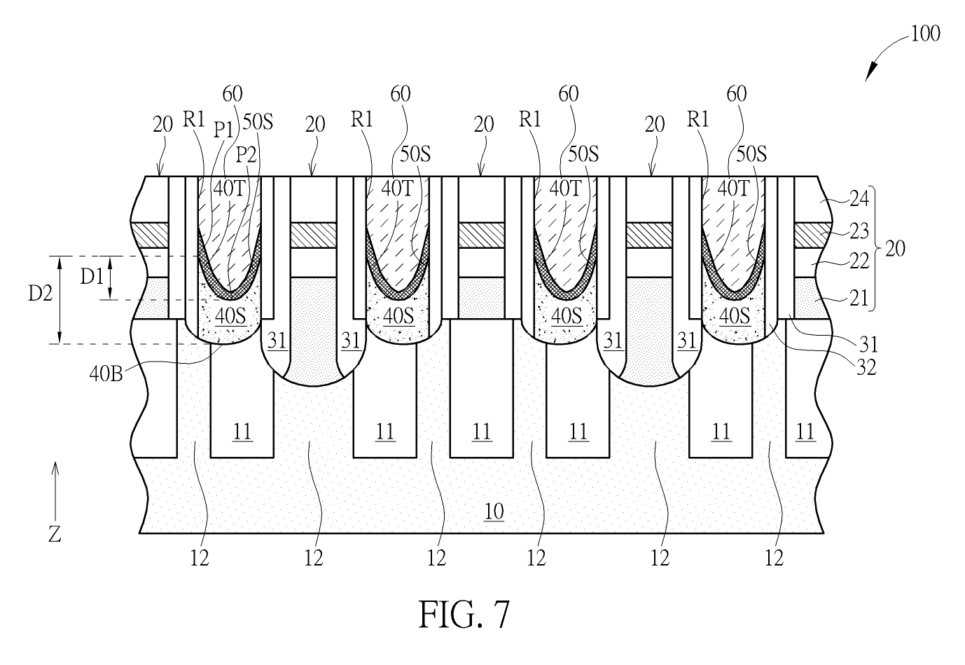

Next, as shown in FIG. 7, a contact structure 60 is formed on the metal silicide 50S, the contact structure 60 is in contact with the metal silicide 50S, so as to be electrically connected to the storage node contact 40S. In some embodiments, the contact structure 60 may be extended upward to form a storage node contact pad, but not limited thereto. Each of the metal silicide layers 50S is formed conformally on the recessed top surface 40T of the corresponding storage node contact 40S. Accordingly, the storage node contact 40S having the recessed top surface 40T in the present embodiment may not only increase the contact area between the storage node contact 40S and the metal silicide layer 50S but also increase the contact area between the contact structure 60 and the metal silicide layer 50S, and both of them are beneficial to reduce the contact resistance between the storage node contact 40S and the contact structure 60. By the above mentioned manufacturing method, a semiconductor memory device 100 as shown in FIG. 7 may be formed.

As shown in FIG. 7, the semiconductor memory device 100 in the present embodiment includes the semiconductor substrate 10 and the storage node contacts 40S. The semiconductor substrate 10 includes the active regions 12. The storage node contacts 40S are disposed on the semiconductor substrate 10. Each of the storage node contacts 40S is in contact with at least one of the active regions 12, and each of the storage node contacts 40S has the recessed top surface 40T. The first distance D1 exists between the topmost point P1 and the lowest point P2 of the recessed top surface 40T in the vertical direction Z perpendicular to the semiconductor substrate 10, the second distance D2 exists between the topmost point P1 of the recessed top surface 40T and the bottom surface 40B of the storage node contact 40S in the vertical direction Z, and the ratio of the first distance D1 to the second distance D2 ranges from 30% to 70%. In a cross-sectional view of the semiconductor memory device 100 (such as FIG. 7), the recessed top surface 40T is a U-shaped recessed top surface, so as to increase the contact area between the storage node contact 40S and other conductive structure formed on the storage node contact 40S, but not limited thereto. In some embodiments, the recessed top surface 40T of the storage node contact 40S in the cross-sectional view may also include other appropriate shapes to increase the contact area. Besides, the semiconductor memory device 100 may further include a plurality of metal silicide layers 50S and a plurality of bit line structures 20. The metal silicide layers 50S are disposed on the recessed top surfaces 40T of the storage node contacts 40S respectively. Each of the metal silicide layers 50S may be formed conformally on the recessed top surface 40T of the corresponding storage node contact 40S, and each of the metal silicide layers 50S maybe a U-shaped metal silicide layer in a cross-sectional view of the semiconductor memory device 100 accordingly, but not limited thereto. The bit line structures 20 are disposed on the semiconductor substrate 10. Each of the bit line structures 20 is disposed corresponding to at least one of the active regions 12, and at least some of the storage node contacts 40S are disposed between the bit line structures 20.

To sum up, in the semiconductor memory device and the manufacturing method thereof in the present invention. Two stacked conductive layers with different etching rate may be used to form the storage node contact having the recessed top surface. The contact area between the storage node contact and other conductive structure formed on the storage node contact may be increased, the contact resistance between the conductive structures and the storage node contact may be reduced, and the electrical operation condition of the semiconductor memory device may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor memory device, comprising:
providing a semiconductor substrate, wherein the semiconductor substrate comprises active regions; and
forming storage node contacts on the semiconductor substrate, wherein each of the storage node contacts contacts at least one of the active regions, and each of the storage node contacts has a recessed top surface, wherein a first distance exists between a topmost point and a lowest point of the recessed top surface in a vertical direction perpendicular to the semiconductor substrate, a second distance exists between the topmost point of the recessed top surface and a bottom surface of the storage node contact in the vertical direction, and a ratio of the first distance to the second distance ranges from 30% to 70%.

2. The manufacturing method of the semiconductor memory device according to claim 1, wherein the steps of forming the storage node contact comprises:
forming grooves on the semiconductor substrate, wherein each of the grooves is formed corresponding to one of the active regions and exposes the corresponding active region;
forming a first conductive layer on the semiconductor substrate, wherein at least a portion of the first conductive layer is filled into the grooves, and each of the grooves is not fully filled with the first conductive layer;
forming a second conductive layer on the first conductive layer, wherein at least a portion of the second conductive layer is filled into the grooves; and
performing an etching back process to the first conductive layer and the second conductive layer to form the storage node contacts in the grooves, wherein the etching rate of the second conductive layer is higher than the etching rate of the first conductive layer in the etching back process.

3. The manufacturing method of the semiconductor memory device according to claim 2, wherein the surface of the first conductive layer in each of the grooves has a recess pointing downward at a center part of the recess, and at least a portion of the second conductive layer is formed in the recess.

4. The manufacturing method of the semiconductor memory device according to claim 2, wherein the density of the first conductive layer is higher than the density of the second conductive layer.

5. The manufacturing method of the semiconductor memory device according to claim 2, wherein the resistivity of the first conductive layer is lower than the resistivity of the second conductive layer.

6. The manufacturing method of the semiconductor memory device according to claim 2, wherein the material of the first conductive layer is the same as the material of the second conductive layer.

7. The manufacturing method of the semiconductor memory device according to claim 6, wherein the first conductive layer is formed by a first deposition process, the second conductive layer is formed by a second deposition process, and the deposition rate of the first deposition process is lower than the deposition rate of the second deposition process.

8. The manufacturing method of the semiconductor memory device according to claim 7, wherein a process temperature of the first deposition process is lower than a process temperature of the second deposition process.

9. The manufacturing method of the semiconductor memory device according to claim 8, wherein the process temperature of the second deposition process ranges from 500° C. to 600° C.

10. The manufacturing method of the semiconductor memory device according to claim 2, wherein the material of the first conductive layer and the material of the second conductive layer include silicon.

11. The manufacturing method of the semiconductor memory device according to claim 2, further comprising:
forming a plurality of bit line structures on the semiconductor substrate, wherein each of the bit line structures is formed corresponding to at least one of the active regions, and at least a portion of the grooves are formed between the bit line structures.

12. The manufacturing method of the semiconductor memory device according to claim 1, further comprising:
forming metal silicide layers on the storage node contacts respectively, wherein each of the metal silicide layers is formed conformally on the recessed top surface of the corresponding storage node contact.

13. The manufacturing method of the semiconductor memory device according to claim 12, wherein each of the metal silicide layers is a U-shaped metal silicide layer in a cross-sectional view of the semiconductor memory device.

14. A semiconductor memory device, comprising:
a semiconductor substrate comprising active regions; and
storage node contacts disposed on the semiconductor substrate, wherein each of the storage node contacts is in contact with at least one of the active regions, and each of the storage node contacts has a recessed top surface, wherein a first distance exists between a topmost point and a lowest point of the recessed top surface in a vertical direction perpendicular to the semiconductor substrate, a second distance exists between the topmost point of the recessed top surface and a bottom surface of the storage node contact in the vertical direction, and a ratio of the first distance to the second distance ranges from 30% to 70%.

15. The semiconductor memory device according to claim 14, wherein the recessed top surface is a U-shaped recessed top surface in a cross-sectional view of the semiconductor memory device.

16. The semiconductor memory device according to claim 14, further comprising metal silicide layers disposed on the recessed top surfaces of the storage node contacts respectively, wherein each of the metal silicide layers is a U-shaped metal silicide layer in a cross-sectional view of the semiconductor memory device.

17. The semiconductor memory device according to claim 14, further comprising:
bit line structures disposed on the semiconductor substrate, wherein each of the bit line structures is disposed corresponding to at least one of the active regions, and at least some of the storage node contacts are disposed between the bit line structures.
